(19) United States
(12) Patent Application Publication
(10) Pub. No.: US 2005/0069143 A1
(43) Pub. Date: Mar. 31, 2005

(54) Filtering for spatial audio rendering

(76) Inventors: Dmitry N. Budnikov, Nizhny Novgorod (RU); Igor V. Chikalov, Nizhny Novgorod (RU); Sergey A. Egorychev, Dzerzhinsk (RU)

Correspondence Address: TROP PRUNER & HU, PC, 8554 KATY FREEWAY, SUITE 100, HOUSTON, TX, 77024, US

(21) Appl. No.: 10/675,649

(22) Filed: Sep. 30, 2003

(51) Int. Cl. H03G 3/00; H04B 15/00

(52) U.S. Cl. 381/63; 381/94.2

(57) ABSTRACT

In one embodiment, spatial audio rendering is achieved by dividing a digitally formatted audio signal into a plurality of time-overlapping windows. The windows may be converted into the frequency domain. Frequency-domain windows are stored in respective cyclical buffers. Windows corresponding to identified reverberation paths are selected and processed (e.g., filtered) according to the characteristics of the respective reverberation path. Processed frequency-domain windows are accumulated and transformed back to the time domain. In one embodiment, head-related transfer functions (HRTFs) are imposed on the frequency-domain windows as a component of the processing.

### BACKGROUND

Accurate spatial reproduction of sound has been demonstrated to significantly enhance the visualization of three-dimensional (3-D) multimedia information, particularly with respect to applications in which it is important to achieve sound localization relative to visual images. Such applications include, without limitation, immersive telepresence; augmented and virtual reality for manufacturing and entertainment; air traffic control, pilot warning, and guidance systems; displays for the visually/or aurally-impaired; home entertainment; and distance learning.

Sound perception is known to be based on a multiplicity of cues that include frequency-dependent level and time differences, and direction-dependent frequency response effects caused by sound reflection in the outer ear, cumulatively referred to as the head-related transfer function (HRTF). The outer ear may be effectively modeled as a linear time-invariant system that is fully characterized in the frequency domain by the HRTF.

Using immersive audio techniques, it is possible to render virtual sound sources in 3-D space using an audio display system, such as a set of loudspeakers or headphones. The goal of such systems is to reproduce a sound pressure level at the listener's eardrums that is equivalent to the sound pressure that would be present if an actual sound source were placed in the location of the virtual sound source. In order to achieve this result, the key characteristics of human sound localization that are based on the spectral information introduced by the HRTF must be considered. The spectral information provided by the HRTF can be used to implement a set of filters that alter nondirectional (monaural) sound in the same way as the real HRTF. Early attempts at the implementation of HRTFs by filtration were based on analytic calculation of the attenuation and delay caused to the soundfield by the head, assuming a simplified spherical model of the head. More recent approaches are based on the measurement of individual or averaged HRTF's that correspond to each desired virtual sound source direction.

In addition to simulating the effects of cues that operate on the human ear, effective spatial audio rendering engines must also accurately simulate the virtual ambient in which the listener is to experience the spatially reproduced sound. To this end, a spatial audio rendering engine typically retrieves a set of reverberation paths that extends between the sound source and the listener. Reverberation paths may be retrieved in accordance with a number of known techniques, prominently including beam tracing. Using the reverberation paths, the spatial audio rendering engine then synthesizes a signal that faithfully replicates an actual listening experience.

Heretofore, realization of the above-described process in a manner that results in a convincing audio simulation has been found to be computationally daunting. Accordingly, what is required is an approach to spatial audio rendering that, in one regard, reduces computational complexity, while concurrently affording the desired degree of simulation quality. In another regard, there exists a need to provide an audio rendering engine that admits of a capability to effect a counterbalance, at a user's discretion, between computational complexity and quality of audio reproduction.

### BRIEF DESCRIPTION OF THE DRAWINGS

The subject spatial audio rendering technique may be better understood by, and its many features, advantages and capabilities made apparent to, those skilled in the art with reference to the Drawings that are briefly described immediately below and attached hereto, in the several Figures of which identical reference numerals (if any) refer to identical or similar elements, and wherein:

FIG. 1 is a graphical representation of the manner in which the physical characteristics of a virtual audio scene may, in one embodiment of the invention, be considered in the design of a spatial audio rendering system.

FIG. 2 is a block diagram of a spatial audio rendering system in accordance with an embodiment of the invention.

FIG. 3 is a block diagram of an exemplary processor-based system into which embodiments of the invention may be incorporated.

Skilled artisans appreciate that elements in Drawings are illustrated for simplicity and clarity and have not (unless so stated in the Description) necessarily been drawn to scale. For example, the dimensions of some elements in the Drawings may be exaggerated relative to other elements to promote and improve understanding of embodiments of the invention.

### DETAILED DESCRIPTION

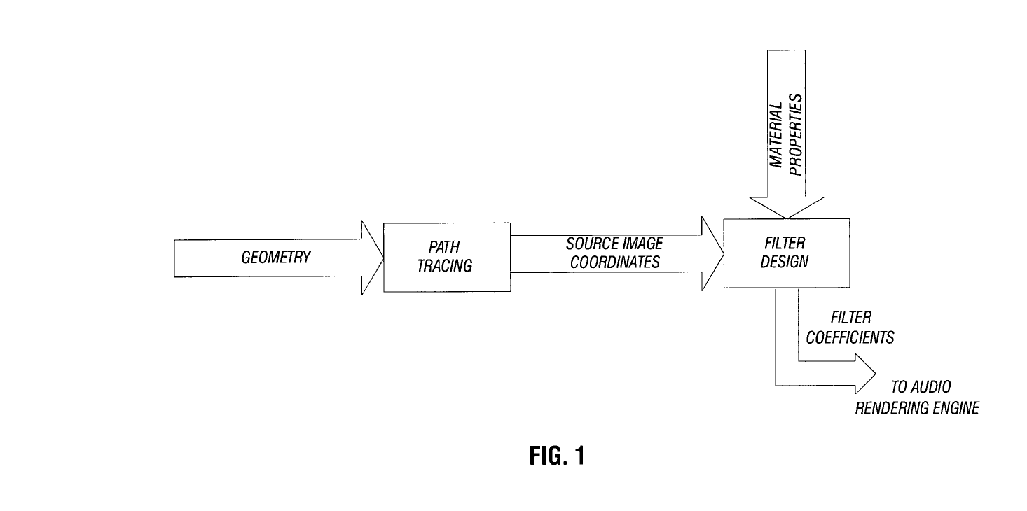

Referring now to FIG. 1, depicted therein is a generalized representation of the methodology according to which, in at least one embodiment of the invention, the physical characteristics of a virtual audio scene may be captured and quantified so that spatial audio rendering may be effectively implemented. The intended result of a spatial audio rendering system is to reproduce (or simulate) the listening response of a human being at a defined position in a virtual scene. The virtual scene be presented, for example, in the application of computer graphics, music playback, sound tracks, and other entertainment content. The listening experience is understood to be a function of the sound sources and the ambient scene geometry and material properties.

Essentially, the spatial audio rendering system operates to capture each reverberation path that couples a sound source to listener. Generally speaking, a “reverberation path” may be here understood to be a trace that represents sound propagation in a scene by taking into account interaction with a single or multiple obstacles. In this regard, beam tracing may be used as a technique for modeling the interaction of sound with obstacles. In general, the beam tracing approach assumes specular reflection of sound beams off relevant obstacles. Simple geometrical calculations allow the definition of reverberation paths from the sound source to the receiver point. Reverberation paths may be represented geometrically as a form of polyline. Source image positions are calculated that constitute each real source in the scene. As result, the scene, which contains a number of obstacles and real sources, is represented as free space that contains a set of source images and a receiver. Equivalently polyline beams emitted by real source and received by receiver are replaced with set of source images, each source image emitting one linear beam (a reverberation path) received by a receiver.

A reverberation path may be said to be “captured” by virtue of mathematical characterization in terms of, for example, the attenuation and delay imparted to a signal source by the reverberation path. Accordingly, for signal processing purposes, each reverberation path may be represented by a filter that imposes a predetermined frequency-dependent attenuation on a source image signal.

Filters corresponding to the respective reverberation paths are coupled to the signal source(s) to generate a reverberant signal that is associated with each reverberation path. The reverberant signals are then accumulated to produce a resultant (simulated) signal. The resultant signal is delivered to the listener through an audio display system, e.g., headphones or loudspeakers.

As graphically represented in FIG. 1, each reverberation path may be traced and represented as an source image that is characterized, according to the geometry of the virtual scene, by a set of coordinates, e.g., azimuth and elevation. As indicated above, a source image technique is used to model sound propagation and interaction with obstacles. Once specular sound reflections are assumed, a scene containing obstacles may be simulated by free space containing real and corresponding source images.

Consider, for example, a scene with one reflecting wall. In this case there exists a direct sound propagation path from source to receiver, as well as one reverberation path from the source to the wall and from the wall to the receiver. The wall may be considered in the nature of mirror. Therefore, the real scene (containing a wall) may be simulated by free space containing a real source and a mirrored (image) source. The foregoing constitutes the essence of the source images construct, as applied to spatial audio rendering.

Be aware, however, that the above example illustrates a first-order source image that models sound interaction with a single obstacle. In general, a scene may contain a greater number of obstacles, and the order of reflections (source images) is then concomitantly much higher. A second order source image can be calculated by mirroring the first order source image in another obstacle. That is, a second-order source image models sound propagation from a source to a receiver, and includes interactions (reflections) with two obstacles, etc.

Material properties, such as frequency-dependent reflection coefficients, of the virtual scene are also relevant and are considered in the design of filters employed to characterize a given respective reverberation path. In this form, the characterization process enables a specific filter design, specified by filter coefficients, that corresponds to each reverberation path. (The manner in which the filters are designed is not considered here to be an aspect of the present invention. Suffice it to say that practitioners skilled in the art of digital signal processing techniques possess expertise adequate to synthesize digital filters that implement frequency-dependent amplitude and delay characteristics. See, for example, D. Schlichtharle, “Digital Filters: Basics and Design,” Springer, 2000.)

As represented in FIG. 1, the characterization process results in, for example, a set of filter coefficients that correspond to each reverberation path. A filtering module, designed in accordance with the coefficients, accepts an input signal that originates with a sound source and filters the signal according to the parameters of the set of source images that correspond to reverberation paths. As indicated above, in one embodiment, filtering comprises the application of a frequency-dependent attenuation factor and the insertion of a time delay. The reverberant signals (filtered source image signals) are accumulated to synthesize a resultant signal. Typically, the resultant signal is divided into at least two channels, e.g., left and right; although in alternative embodiments, more than two channels may be created. The output channels may then be applied to one or more audio display systems, such as, for example, a loudspeaker system or a headphone system.

In alternative embodiments, prior to the accumulation of the reverberant signals and delivery of an output signal to the audio display system, an additional filter (which may be considered a “post-filter”) may be applied. The characteristics of the post-filters are dependent on the nature of the audio display system and are also dependent on the coordinates of the source images. For example, as indicated above, HRTFs may be applied to the reverberant signals prior to accumulation and application to a headphone system.

In addition, in applications where a loudspeaker system is incorporated as an audio display device, filtering appropriate to the Ambisonic technique may be applied. As is known to those skilled in the art, in the application of the Ambisonic technique, an output signal for each speaker is produced as a weighted sum of individual reverberation path signals. The weight coefficients may be calculated from the source image coordinates and loudspeaker layout.

Ambisonic sound processing is a set of techniques for recording, studio processing and reproduction of the complete sound field experienced during the original performance. Ambisonic technology decomposes the directionality of the sound field into spherical harmonic components. The approach uses all speakers in a system to cooperatively recreate these directional components. That is to say, speakers to the rear of the listener help localize sounds in front of the listener, and vice versa. Ambisonic decoder design aims to satisfy simultaneously and consistently as many as possible of the mechanisms used by the ear/brain to localize sounds. The theory takes account of non-central as well as central listening positions. In an Ambisonic decoder, the spherical harmonic direction signals are passed through a set of shelf filters that have different gains at low and high frequencies, wherein the filter gains are designed to match the panoply of mechanisms in which the ear and brain localize sounds. Localisation mechanisms operate below and above about 700 Hertz (Hz). The speaker feeds are then derived by passing the outputs from the shelf filters through a simple amplitude matrix. A characteristic of Ambisonic decoder technology is that it is only at this final stage of processing that the number and layout of speakers is considered.

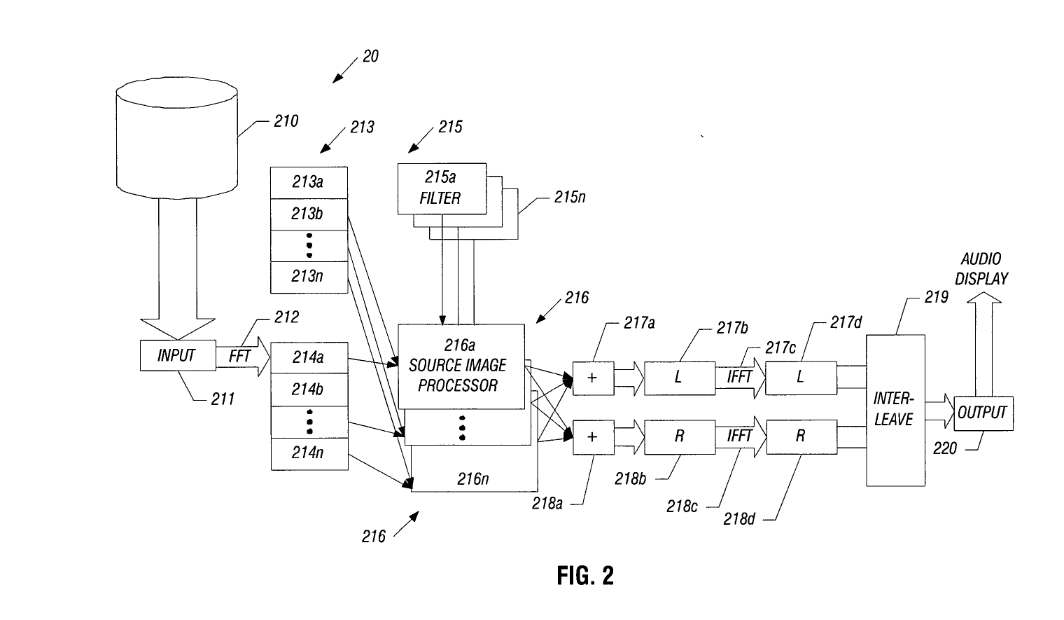

For a thorough understanding of the subject spatial audio rendering technique, refer now to FIG. 2, which is a block diagram of a spatial audio rendering system 20 that is implemented in accordance with one embodiment of the invention. As illustrated in FIG. 2, system 20 comprises an input stage 211 that may be coupled to an audio input signal source 210. In one embodiment, audio input signals that are stored in, or are transmitted from, signal source 210 may be provided as digital files, such as, for example, AFFI, WAV or MP3 files. However, the scope of the invention is not constrained by the nature of input files, and embodiments of the invention extend to all manner of digital audio files, now known or hereafter developed.

Input stage 211, in one embodiment, may be constructed to divide the digital audio input signal into a number of timewise-overlapping windows.

There exist numerous techniques to divide a time-domain input signal into windows. The primary purpose of the signal windowing is a further calculation of the frequency domain signal spectrum, which may be accomplished, for example, using a Fast Fourier Transform (FFT). 50% overlapped sinusoidal windows may be typical in one embodiment of the invention. The length of the window, in one embodiment, may vary from 256 to 2048 samples of the input time-domain signal. Other arrangements of the window, including the overlapping ratio and length are also possible. Skilled practitioners, in the judicious exercise of a designer's discretion, may select window shape, overlapping ratio and length to obtain more nearly optimal results that are tailored for an individual application. However, window shape, overlapping ratio and window length are not constraints on the scope of the invention.

The output of input stage 211 is coupled to an FFT (Fast Fourier Transform) module 212. In a manner well understood by practitioners acquainted with digital signal processing (DSP) techniques, FFT module 212 operates to transform each of the timewise-overlapping windows created by input stage 211 to a frequency-domain equivalent, that is, into a frequency-transformed window. The frequency-transformed windows are stored in a cyclic input buffer 214. In practice, cyclic buffer 214 comprises a number of distinct buffers 214a, 214b, . . . , 214n, each of which stores one of the frequency-transformed windows. The length of the buffers may be designed to correspond to the length of the longest delay interposed by a reverberation path. In general, a buffer adequate to insert a delay of one second (at the applicable system clock rate) may generally be sufficient, although other implementations would suggest different buffer sizes.

A spatial audio rendering engine 216 may be constituted from a plurality of source image processing kernels 216a, . . . , 216n. In the manner indicated in FIG. 2, each of the source image processing kernels may be selectably coupled (as described below) to an output of one of the cyclic input buffers 214a, . . . , 214n. Coupling of an input buffer to one of the source image processing kernels may be effected under software control, for example.

In addition, and as depicted in FIG. 2, in operation, each of the source image processing kernels 216a, . . . , 216n is also associated with one of the filters 215a, . . . , 215n that constitute filter bank 215. Filters 215a, . . . , 215n are constructed, as described above and depicted in FIG. 1, to characterize the reverberation paths alluded to above. That is, each of the filters 215a, . . . , 215n in filter bank 215 is designed to impart to a source image a frequency-dependent attenuation that simulates a reverberation path. Accordingly, each of the filters 215a, . . . , 215n corresponds to a reverberation path. Filters 215a, . . . , 215n may be realized as digital filters having characteristics that are defined by predetermined filter coefficients.

In one embodiment, source image processing kernels 216a, . . . , 216n operate in the following manner, under software control, for example, to process selected ones of the frequency-transformed windows stored by cyclic input buffer 214. Specifically, in one embodiment, for each reverberation path that has been identified with respect to a virtual scene, a signal delay is determined for each path between a source image and the listener. The delay may be determined in accordance with any of a number of techniques, such as, for example, by the acquisition of empirical data or as a result of a mathematical calculation, based on, for example, the distance between the source image and the listener. Software simulation may also be employed. Once a signal delay is attributed to each reverberation path, the transformed window having a delay that is closest to the delay attributed to the reverberation path is identified and thereby matched to reverberation path. In this regard, it should be noted that, as a matter to be determined in the judicious discretion of the system designer, smaller time-delay distances between consecutive frequency-transformed windows stored in buffer 214 result in finer granularity in the match between reverberation path, i.e., source images and available transformed windows. However, the improvement in matching is acquired at the expense of an increase in the number of frequency-transformed windows that must be available and, therefore, the number of FFTs that must be performed.

In the above-described manner, the transformed windows stored in respective ones of the cyclic input buffers 214a, . . . 214n are selected for concurrent processing by associated ones of the source image processing kernels 216a, . . . , 216n. Essentially, the source image processors operate to apply an appropriate one of the filters 215a, 215b, . . . , 215n to each of the selected transformed windows. That is to say, in one embodiment, given a transformed window that has been matched to a reverberation path and that has been assigned for processing by a source image processing kernel, then processing is performed in accordance with parameters established by the filter that corresponds to the reverberation path.

Consequently, the source image processing kernels concurrently provide a plurality of output signals, which may be denominated here as “frequency-domain reverberants.”Each of the frequency-domain reverberants corresponds to a delayed and attenuated version of a source image that is associated with a reverberation path. Delay is effectively imparted to a source image operation of the cyclic buffers. Frequency-dependent attenuation is imparted by virtue of the application of a particular filter that has been characterized in conformance with the reverberation path.

In some embodiments, the system may also include a table 213 of HRTFs. The table (which may constitute any form of suitable storage device) contains a number of HRTFs that, much like filters 215a, . . . , 215n, are matched to an source image reverberation path). Consequently, as transformed windows are selectably applied to a respective source image processing kernels for processing in accordance with appropriately matched filters 215a . . . 215n, so too are appropriate ones of HRTFs 213a, 213b, . . . , 213n. Therefore, in such an embodiment, the reverberant outputs of the source image processing kernels represent a delayed version of an source image that has been specifically attenuated by one of filters 215a . . . 215n to conform to the attenuation interposed by the reverberation path and by one of the HRTFs 213a, 213b, . . . , 213n to simulate the auditory response of a human being to an source image that is displayed through headphones. Recall here that HRTFs differ as a function of source image coordinates. Therefore, HRTFs are likewise matched to specific source images.

As illustrated in FIG. 2, the outputs of the source image processing kernels (i.e., reverberants) are, in one embodiment, coupled to parallel left (L) and right (R) channels 217 and 218, respectively. Each channel comprises a respective signal combiner (217a, 218a), output buffer (217b, 218b), Inverse Fast Fourier Transform (IFFT) module (217c, 218c), and interstage buffer (217d, 218d).

As to operation, the concurrent reverberant outputs of appropriate ones of the source image processing kernels are coupled to the inputs of the respective left and right channel signal combiners 217a and 217b. The outputs of the signal combiners, denominated here “frequency-domain resultants,” are buffered in respective left and right output buffers 217b and 218b and are applied to respective IFFT modules 217c and 218c. IFFT modules 217c and 218c transform the frequency-domain resultant signals into the time-domain equivalents, i.e., time-domain resultants. The left and right time-domain resultant signals are coupled through respective interstage buffers 217d and 218d to an interleave module 219.

In a manner familiar to those skilled in the art, interleave module 219 imparts a standard formatting convention that is applicable to the storage and transmission of multichannel audio data. For example, with respect to stereophonic audio data that comprises a Left (L) and Right (R) channel, samples are taken in a L, R, L, R, L, R, . . . sequence. Interleave module 219 operates to interleave a sequence of left channel signals (L, L, L, . . . ) and right channel signals (R, R, R, . . . ) to produce an interleaved channel sequence, L, R, L, R, L, R, . . . , that can be stored in a WAV file or played back using a computer audio card. The output of interleave module 219 is coupled to an audio display device, which may be, for example, a loudspeaker system or a headphone set, although other forms of audio display devices, now known or hereafter developed, may be used with the invention.

The embodiment described immediately above is particularly advantageous in applications where the number of reverberation paths is relatively small (say, up to 100) and relatively fine granularity is required of the source images. In this context, it is deemed appropriate that the input signal, initially provided to the spatial audio rendering engine in the time domain, be converted to the frequency domain and stored in a cyclic buffer as frequency-domain transforms. Consequently, one FFT is required for each channel (e.g. Left and Right).

Alternately, the audio input may be coupled directly (without FFT) to the cyclic buffer and stored in the time domain. Depending on the reverberation path and corresponding time delay, the signals stored in respective buffers are selected and transformed through the application of a respective FFT module, so that one FFT module is required for each reverberation path. After application of the FFT, reverberation path filters, HRTF filters and other (if any) filters may be applied to the frequency-domain signal. An IFFT is applied to each channel signal after summation of the individual reverberation path signals.

Furthermore, in some applications the number of reverberation paths may be large, greater than 100, for example. Specifically, in a small room with complex geometry and highly absorbent materials, the reverberation time is typically quite short, but the number of reverberation paths may be significant. Consequently, a large number of reverberation paths will share a similar delay. In this context, an alternative embodiment may be warranted in which the use of a matrix filter may be invoked. According to the approach, filters corresponding to reverberation paths that are matched to the same window may be aggregated. As a result, filtration is reduced to the multiplication of two matrices of size (M)×(N), where M is the number of windows and N is the length of each window. In this embodiment, the computational complexity of filtration does not increase with the number of reverberation paths. However, when the number of reverberation paths is small, the matrix filter is then only sparsely populated. In this context, the matrix filter approach imposes substantial computational overhead.

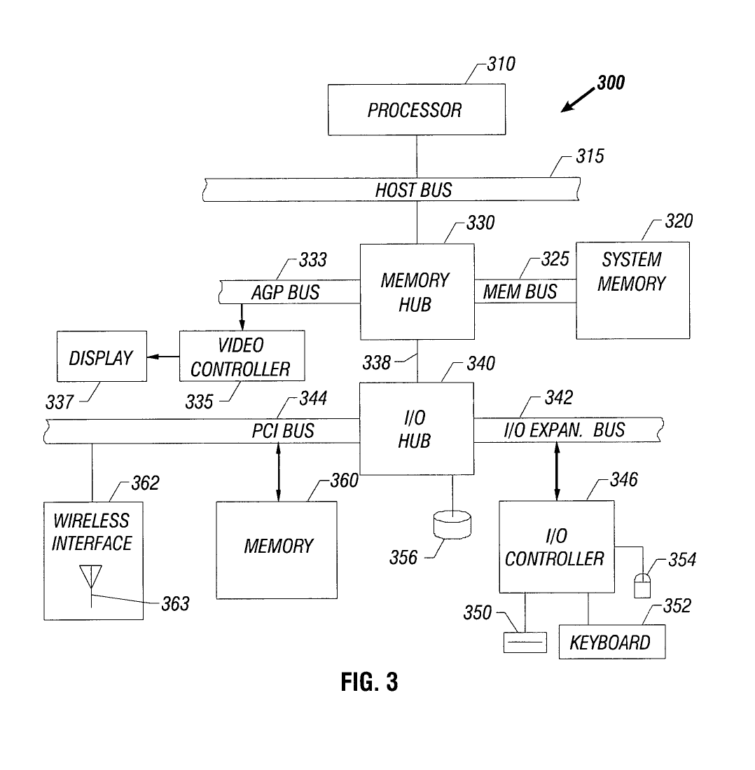

FIG. 3 is a block diagram of an exemplary processor-based system into which embodiments of the invention may be incorporated. With specific reference now to FIG. 3, in one embodiment the invention may be incorporated into a system 300. System 300 is seen to include a processor 310, which may include a general-purpose or special-purpose processor. Processor 310 may be realized as a microprocessor, microcontroller, an application-specific integrated circuit (ASIC), a programmable gate array (PGA), and the like. As used herein, the term “computer system” may refer to any type of processor-based system, such as a mainframe computer, a desktop computer, a server computer, a laptop computer, an appliance, a set-top box, or the like.

In one embodiment, processor 310 may be coupled over a host bus 315 to a memory hub 330, which, in turn, may be coupled to a system memory 320 via a memory bus (MEM) 325. Memory hub 330 may also be coupled over an Advanced Graphics Port (AGP) bus 333 to a video controller 335, which may be coupled to a display 337. AGP bus 333 may conform to the Accelerated Graphics Port Interface Specification, Revision 2.0, published May 4, 1998, by Intel Corporation, Santa Clara, Calif.

Memory hub 330 may also be coupled (via a hub link 338) to an input/output (I/O) hub 340 that is coupled to a input/output (I/O) expansion bus 342 and to a Peripheral Component Interconnect (PCI) bus 344, as defined by the PCI Local Bus Specification, Production Version, Revision 2.1 dated in June 1995. The I/O expansion bus (I/O EXPAN) 342 may be coupled to an I/O controller 346 that controls access to one or more I/O devices. As shown in FIG. 3, these devices may include in one embodiment storage devices, such as a floppy disk drive 350, and input devices, such as keyboard 352 and mouse 354. I/O hub 340 may also be coupled to, for example, hard disk drive 356 and compact disc (CD) drive (not shown). It is to be understood that other storage media may also be included in computer system 300.

In an alternate embodiment, the I/O controller 346 may be integrated into the I/O hub 340, as may other control functions. PCI bus 344 may also be coupled to various components including, for example, a memory 360 that in one embodiment, may be a multilevel, segmented unified memory device much as has been described herein. Additional devices may be coupled to the I/O expansion bus 342 and to PCI bus 344. Such devices include an input/output control circuit coupled to a parallel port, a serial port, a non-volatile memory, and the like.

Further shown in FIG. 3 is a wireless interface 362 coupled to the PCI bus 344. The wireless interface may be used in certain embodiments to communicate with remote devices. As shown in FIG. 3, wireless interface 362 may include a dipole or other antenna 363 (along with other components not shown in FIG. 3). While such a wireless interface may vary in different embodiments, in certain embodiments the interface may be used to communicate via data packets with a wireless wide area network (WWAN), wireless local-area network (WLAN), a BLUETOOTH™—compliant device or system or another wireless access point. In various embodiments, wireless interface 362 may be coupled to system 300, which may be a notebook personal computer, via an external add-in card, or an embedded device. In other embodiments wireless interface 362 may be fully integrated into a chipset of system 300.

Although the description makes reference to specific components of the system 300, it is contemplated that numerous modifications and variations of the described and illustrated embodiments may be possible. Moreover, while FIG. 3 is a block diagram of a particular system (i.e., a notebook personal computer), it is to be understood that embodiments of the present invention may be implemented in another wireless device such as a cellular phone, personal digital assistant (PDA) or the like.

In addition, skilled practitioners recognize that embodiments may also be realized in software (or in the combination of software and hardware) that may be executed on a host system, such as, for example, a computer system, a wireless device, or the like. Accordingly, such embodiments may comprise an article in the form of a machine-readable storage medium onto which there are written instructions, data, etc. that constitute a software program that defines at least an aspect of the operation of the system. The storage medium may include, but is not limited to, any type of disk, including floppy disks, optical disks, compact disk read-only memories (CD-ROMs), compact disk rewritables (CD-RWs), and magneto-optical disks, and may include semiconductor devices such as read-only memories (ROMs), random access memories (RAMs), erasable programmable read-only memories (EPROMs), electrically erasable programmable read-only memories (EEPROMs), flash memories, magnetic or optical cards, or any type of media suitable for storing electronic instructions. Similarly, embodiments may be implemented as software modules executed by a programmable control device, such as a computer processor or a custom designed state machine.

Accordingly, from the Description above, it should be abundantly clear that embodiments of the subject invention constitute a substantial embellishment in spatial audio rendering techniques. To wit: an algorithm for spatial audio rendering in which filters are applied to simulate sound reverberation in a computationally effective manner. In addition, because that architecture of the spatial audio rendering system incorporates a filter bank having parameters that are tunable to a predetermined number of reverberation paths, the system facilitates an exercise of design discretion in which computational complexity and quality of audio reproduction may be balanced.

While the present invention has been described with respect to a limited number of embodiments, those skilled in the art will appreciate numerous modifications and variations therefrom. It is intended that the appended claims cover all such modifications and variations as fall within the true spirit and scope of this present invention.

1. A method comprising:
dividing an input signal into a plurality of time-overlapping windows;
transforming time-overlapping windows so as to create a plurality of frequency-transformed windows;
processing selected ones of the frequency-transformed windows;
adding processed frequency-transformed windows to form a frequency-domain resultant; and
converting the frequency-domain resultant into a time-domain resultant.

2. A method as defined in claim 1, further comprising:
selecting frequency-transformed windows for processing in accordance with reverberation paths, wherein each of the reverberation paths is associated with a respective delay.

3. A method as defined in claim 2, further comprising:
selecting a frequency-transformed window that incorporates a time shift that is closest to the delay to the reverberation path.

4. A method as defined in claim 1, wherein processing selected ones of the frequency-transformed windows comprises applying a first filter that corresponds to a reverberation path.

5. A method as defined in claim 4, wherein the first filter effects a frequency-dependent attenuation that corresponds to a respective reverberation path.

6. A method as defined in claim 5, wherein processing selected ones of the frequency-transformed windows further comprises applying a head-related transfer function.

7. A method as defined in claim 6, wherein the head-related transfer function corresponds to a respective reverberation path.

8. A method as defined in claim 7, wherein the head-related transfer function corresponds to positional coordinates of the reverberation path.

9. An apparatus comprising:
an input stage to couple to a source of input signals and to divide an input signal into timewise-overlapping windows;
a frequency transform module coupled to the input stage to transform each of the timewise-overlapping windows into a respective frequency-transformed window; and
a processor to select frequency-transformed windows and to filter each of the selected windows in accordance with a respective filter so as to produce a filtered frequency-transformed window.

10. An apparatus as defined in claim 9, wherein the processor is adapted to select frequency-transformed windows by matching a frequency-transformed window to a source image.

11. An apparatus as defined in claim 10, wherein a source image corresponds to a reverberation path of an audio signal.

12. An apparatus as defined in claim 10, further comprising:
a table to store a plurality of transfer functions, each of the transfer functions corresponding to at least one source image

13. An apparatus as defined in claim 12, wherein a source image corresponds to a reverberation path of an audio signal.

14. An apparatus as defined in claim 13, wherein each of the transfer functions is a head-response transfer function that corresponds to a reverberation path.

15. An apparatus as defined in claim 10, further comprising:
a combiner coupled to the processor to receive a plurality of the frequency-transformed windows and to provide combined windows at an output; and
an inverse frequency transform module coupled to an output of the combiner to transform combined windows into the time domain.

16. An apparatus as defined in claim 12, wherein the processor comprises a plurality of source-image processors, wherein each source-image processor:
(i) is coupled to receive a frequency-transformed window that is matched to a respective source image;
(ii) is coupled to the table to receive a transfer function associated with a respective source image; and
(iii) is coupled to receive filter coefficients that correspond to the respective source image.

17. An article comprising a machine-readable storage medium containing instructions that, if executed, enable a system to:
divide an input signal into a plurality of time-domain windows;
transform each of the time-domain windows into the frequency domain so as to create a plurality of frequency-transformed windows;
process selected ones of the frequency-transformed windows;
combine the processed frequency-transformed windows to form a frequency-domain resultant; and
convert the frequency-domain resultant into a time-domain resultant.

18. An article as defined in claim 17, further comprising instructions that, if executed, enable the system to:
select frequency-transformed windows for processing in accordance with one or more source images.

19. An article as defined in claim 18, further comprising instructions that, if executed, enable the system to select frequency-transformed windows for processing by matching a frequency-transformed window to a delay corresponding to a respective source image.

20. An article as defined in claim 18, further comprising instruction that, if executed, enable the system to filter the frequency-transformed window in accordance with parameters that are derived from the source image.

21. An article as defined in claim 20, further comprising instructions that, if executed, enable the system to filter the frequency-transformed window in accordance with a Head Response Transfer Function that corresponds to the source image.

22. A spatial audio rendering engine comprising:
an input stage to divide an input signal into timewise-overlapping windows;
a transform module to transform each of the timewise-overlapping windows into a frequency-transformed window;
a plurality of source image processing kernels, each of the kernels to process a transformed window in accordance with parameters corresponding to a source image; and
an inverse transform module coupled to the source image processing kernels to provide a time-domain signal derived from frequency-transformed windows processed by the processing kernels.

23. A spatial audio rendering engine as defined in claim 22, wherein the source image processing kernels are constructed to process selected frequency-transformed windows in accordance with filter functions that correspond to respective ones of the source images.

24. A spatial audio rendering engine as defined in claim 23, further comprising a plurality of Head Related Transfer Functions to selectably coupled to respective ones of the source image processing kernels for filtering a transformed windows in a manner that simulates the response of a human ear to the respective source image provided to an audio display device.

25. A spatial audio rendering engine as defined in claim 23, wherein source image processing kernels are constructed to process frequency-transformed windows that are time-delay matched to respective source images.

26. A spatial audio rendering engine as defined in claim 25, further comprising:
a signal combiner coupled to outputs of source image processing kernels to provide an output window representing a combination of the outputs of the source image processing kernels.

27. A spatial audio rendering engine as defined in claim 26, further comprising:
an inverse transform module coupled to the signal combiner to transform the output window signal to a time-domain signal.

28. A spatial audio rendering engine as defined in claim 27, further comprising:
an interleave module coupled to the inverse transform module to provide an output signal to an audio display device.

29. A system comprising:
a spatial audio rendering engine comprising:
an input stage to couple to a source of input signals and to divide an input signal into timewise-overlapping windows;
a frequency transform module coupled to the input stage to transform each of the timewise-overlapping windows into a respective frequency-transformed window; and
a processor to select frequency-transformed windows and to filter each of the selected frequency-transformed windows in accordance with a respective filter so as to produce a filtered frequency-transformed window; and
an audio display device.

30. A system as defined in claim 29, further comprising:
a buffer coupled to the frequency transform module to store respective ones of the frequency-transformed windows.
